(19) United States
(12) Patent Application Publication
(10) Pub. No.: US 2022/0390519 A1
(43) Pub. Date: Dec. 8, 2022

(54) SHORT-CIRCUIT DETECTION DEVICE AND SHORT-CIRCUIT DETECTION METHOD

(71) Applicant: Mitsubishi Electric Corporation, Tokyo (JP)

(72) Inventors: Yuji TAKIZAWA, Tokyo (JP); Haruyuki KOMETANI, Tokyo (JP); Atsushi YAMAMOTO, Tokyo (JP); Susumu MAEDA, Tokyo (JP); Nobuaki MUROKI, Tokyo (JP)

(73) Assignee: Mitsubishi Electric Corporation, Tokyo (JP)

(21) Appl. No.: 17/770,053

(22) PCT Filed: Dec. 26, 2019
(86) PCT No.: PCT/JP2019/051236

§ 371 Date: Apr. 19, 2022

(51) Int. Cl. G01R 31/34; H03K 5/24; G01R 31/52; G01R 33/02

(52) U.S. Cl. CPC G01R 31/346; H03K 5/24; G01R 31/52; G01R 33/02

(57) ABSTRACT

The short-circuit detection device according to the present disclosure includes: a signal acquisition unit configured to acquire, from a magnetic flux detector configured to detect a magnetic flux generated in a gap between a rotor and a stator of a rotary electric machine, one detected signal based on the magnetic flux and set the one detected signal as a first detected signal and a second detected signal; a signal processing unit configured to perform frequency analysis on the first detected signal, and generate and decode a voltage signal simulating a voltage state assumed in a normal case; and a signal comparison unit configured to perform comparison between a decoded signal obtained through the decoding by the signal processing unit and the second detected signal transmitted from the signal acquisition unit, to detect a short-circuit in a field winding of the rotary electric machine.

### TECHNICAL FIELD

The present disclosure relates to a short-circuit detection device and a short-circuit detection method for detecting a short-circuit in a field winding of a rotary electric machine.

### BACKGROUND ART

As a device for detecting a short-circuit in a field winding of a turbine electric generator which is an example of a rotary electric machine, a device in which a magnetic flux detector such as a search coil for detecting a magnetic flux generated in a gap between a rotor and a stator detects a change in the field magnetic flux due to a short-circuit in a field winding has been proposed. The device for detecting a short-circuit in the field winding makes use of the characteristic that, unlike in a normal magnetic pole which is one magnetic pole having experienced no short-circuit among two magnetic poles of the rotor, a field magnetic flux amount decreases owing to decrease in the number of turns of the field winding in a short-circuit magnetic pole which is the other magnetic pole having experienced a short-circuit.

The short-circuit detection device is configured to detect occurrence of a short-circuit by comparing a field magnetic flux amount resulting from the decrease due to the occurrence of the short-circuit with a normal-case field magnetic flux amount which is a field magnetic flux amount acquired in advance when no short-circuit has occurred (see, for example, Patent Document 1).

Meanwhile, another short-circuit detection device is configured to detect occurrence of a short-circuit by comparison between field magnetic flux amounts acquired at two magnetic poles at rotation angles that are different from each other by 180 degrees (see, for example, Patent Document 2).

### CITATION LIST

### Patent Document

Patent Document 1: Japanese Laid-Open Patent Publication No. 2009-213346

Patent Document 2: U.S. Pat. No. 8,781,765

### SUMMARY OF THE INVENTION

### Problems to be Solved by the Invention

However, in such conventional technologies, a preliminary measurement needs to be performed to decrease an angle error such that an error of a difference voltage due to an angle error in the waveform of a field magnetic flux and a difference based on the decrease, in the field magnetic flux, that is caused by occurrence of a short-circuit in a field winding are distinguished from each other. In the preliminary measurement, an adverse influence of load fluctuation due to change in an operation condition is likely to be inflicted, and the preliminary measurement is likely to result in erroneous detection and decrease in the accuracy of short-circuit detection.

The present disclosure has been made to solve the above drawback, and an object of the present disclosure is to provide a short-circuit detection device and a short-circuit detection method that enable more accurate detection of a short-circuit in a field winding by suppressing erroneous detection and decrease in the accuracy of short-circuit detection which result from a preliminary measurement.

### Solution to the Problems

A short-circuit detection device according to the present disclosure includes: a signal acquisition unit configured to acquire, from a magnetic flux detector configured to detect a magnetic flux generated in a gap between a rotor and a stator of a rotary electric machine, one detected signal based on the magnetic flux and set the one detected signal as a first detected signal and a second detected signal; a signal processing unit configured to perform frequency analysis on the first detected signal, and generate and decode a voltage signal simulating a voltage state assumed in a normal case; and a signal comparison unit configured to perform comparison between a decoded signal obtained through the decoding by the signal processing unit and the second detected signal transmitted from the signal acquisition unit, to detect a short-circuit in a field winding of the rotary electric machine.

A short-circuit detection device according to the present disclosure includes: a signal acquisition unit configured to acquire, from a magnetic flux detector configured to detect a magnetic flux generated in a gap between a rotor and a stator of a rotary electric machine, detected signals for different magnetic poles, the detected signals being based on the magnetic flux, the detected signals being acquired as a first detected signal and a second detected signal; a signal processing unit configured to perform frequency analysis on the first detected signal, and generate and decode a voltage signal having a phase that matches a phase of the second detected signal; and a signal comparison unit configured to perform comparison between a decoded signal obtained through the decoding by the signal processing unit and the second detected signal, to detect a short-circuit in a field winding of the rotary electric machine.

A short-circuit detection method according to the present disclosure includes: a step of acquiring, from a magnetic flux detector configured to detect a magnetic flux generated in a gap between a rotor and a stator of a rotary electric machine, one detected signal based on the magnetic flux, and setting the one detected signal as a first detected signal and a second detected signal; a step of performing frequency analysis on the first detected signal, and generating and decoding a voltage signal simulating a voltage state assumed in a normal case; and a step of performing comparison between a decoded signal obtained through the decoding and the second detected signal, to detect a short-circuit in a field winding of the rotary electric machine.

A short-circuit detection method according to the present disclosure includes: a step of acquiring, from a magnetic flux detector configured to detect a magnetic flux generated in a gap between a rotor and a stator of a rotary electric machine, detected signals for different magnetic poles, the detected signals being based on the magnetic flux, the detected signals being acquired as a first detected signal and a second detected signal; a step of performing frequency analysis on the first detected signal, and generating and decoding a voltage signal having a phase that matches a phase of the second detected signal; and a step of performing comparison between a decoded signal obtained through the decoding and the second detected signal, to detect a short-circuit in a field winding of the rotary electric machine.

### Effect of the Invention

In the short-circuit detection device according to the present disclosure, one detected signal having been acquired is set as a first detected signal and a second detected signal, and the second detected signal and a decoded signal obtained through decoding of a voltage signal that has been generated from the first detected signal and that simulates a state assumed in a normal case, are compared with each other. Consequently, it is possible to detect a short-circuit in a field winding while suppressing erroneous detection and decrease in the accuracy of short-circuit detection which result from a preliminary measurement.

In the short-circuit detection device according to the present disclosure, a second detected signal and a decoded signal obtained through decoding of a voltage signal that has a phase adjusted to a phase of the second detected signal and that has been generated from a first detected signal acquired at a magnetic pole different from a magnetic pole for the second detected signal, are compared with each other. Consequently, it is possible to detect a short-circuit in a field winding while suppressing erroneous detection and decrease in the accuracy of short-circuit detection which result from a preliminary measurement.

In the short-circuit detection method according to the present disclosure, one detected signal having been acquired is set as a first detected signal and a second detected signal, and the second detected signal and a decoded signal obtained through decoding of a voltage signal that has been generated from the first detected signal and that simulates a state assumed in a normal case, are compared with each other. Consequently, it is possible to detect a short-circuit in a field winding while suppressing erroneous detection and decrease in the accuracy of short-circuit detection which result from a preliminary measurement.

In the short-circuit detection method according to the present disclosure, a second detected signal and a decoded signal obtained through decoding of a voltage signal that has a phase adjusted to a phase of the second detected signal and that has been generated from a first detected signal acquired at a magnetic pole different from a magnetic pole for the second detected signal, are compared with each other. Consequently, it is possible to detect a short-circuit in a field winding while suppressing erroneous detection and decrease in the accuracy of short-circuit detection which result from a preliminary measurement.

### BRIEF DESCRIPTION OF THE DRAWINGS

FIG. 1 is a configuration diagram of a short-circuit detection device according to embodiment 1 and a rotary electric machine.

FIG. 2 is a hardware configuration diagram of the short-circuit detection device according to embodiment 1.

FIG. 3 shows exemplary voltage waveforms detected by a search coil in embodiment 1.

FIG. 4 is an exemplary flowchart of a short-circuit detection method according to embodiment 1.

FIG. 5 shows exemplary diagrams showing graphs of frequencies in each of cases, i.e., a normal case, a short-circuited case, and a simulated normal case, in embodiment 1.

FIG. 6 shows exemplary graphs indicating difference voltage waveforms at respective angle errors, and an exemplary graph indicating difference voltages at respective angle errors, in embodiment 1.

FIG. 7 is a configuration diagram of a short-circuit detection device according to embodiment 2 and a rotary electric machine.

FIG. 8 is an exemplary flowchart of a short-circuit detection method according to embodiment 2.

### DESCRIPTION OF EMBODIMENTS

### Embodiment 1

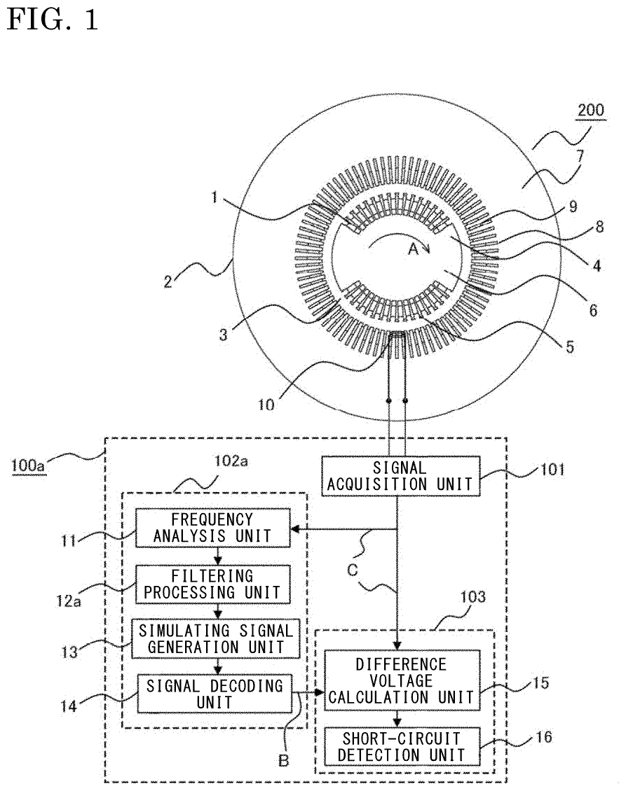

FIG. 1 is a configuration diagram of a short-circuit detection device 100a according to the present embodiment and a rotary electric machine 200 to which the short-circuit detection device 100a is applied. In the present embodiment, a turbine electric generator is used as an example of the rotary electric machine 200.

Firstly, a configuration of the rotary electric machine 200 will be described.

As shown in FIG. 1, the rotary electric machine 200 includes a rotatably provided rotor 1 and a stator 2 provided outward of the rotor 1. An outer circumferential portion of the rotor 1 and an inner circumferential portion of the stator 2 are opposed to each other with a gap 3 interposed therebetween. A plurality of rotor slots 5 are formed in a rotor core 4 of the rotor 1. Field windings connected in series are wound in the plurality of rotor slots 5.

Each field winding is excited with direct current from an external power supply such that the rotor core 4 is excited at two poles. Consequently, two magnetic poles 6 are formed on the rotor core 4.

A plurality of stator slots 8 are formed in a stator core 7 of the stator 2. A multiphase winding 9 is wound in the plurality of stator slots 8. The multiphase winding 9 is excited with alternating current such that a rotating magnetic field is generated in the gap 3.

The rotary electric machine 200 shown in FIG. 1 is a two-poles electric generator having 32 rotor slots 5 and 84 stator slots 8. Arrow A in the clockwise direction in FIG. 1 indicates the rotation direction of the rotor 1.

A magnetic flux detector 10 which detects a magnetic flux in a radial direction generated in the gap 3 between the rotor 1 and the stator 2 of the rotary electric machine 200 is provided so as to be fixed to a portion of the stator 2 that faces the gap 3. The magnetic flux detector 10 is, for example, a search coil. A main magnetic flux generated in the gap 3 and a leakage magnetic flux in each rotor slot 5 interlink with the magnetic flux detector 10. Thus, a voltage based on each magnetic flux interlinking with the magnetic flux detector 10 is generated between terminals at both ends of the magnetic flux detector 10. The magnetic flux interlinking with the magnetic flux detector 10 is distributed such that a search coil voltage signal based on the amount of the interlinking magnetic flux is outputted from the magnetic flux detector 10 correspondingly to the rotation angle of the rotor 1.

A short-circuit detection device 100a is connected to the magnetic flux detector 10. The short-circuit detection device 100a includes a signal acquisition unit 101, a signal processing unit 102a, and a signal comparison unit 103.

The signal acquisition unit 101 acquires a voltage waveform of a detected signal acquired by the magnetic flux detector 10.

With the detected signal acquired from the signal acquisition unit 101 being set as a first detected signal, the signal processing unit 102a generates and outputs a decoded signal corresponding to the first detected signal. The signal processing unit 102a includes a frequency analysis unit 11, a filtering processing unit 12a, a simulating signal generation unit 13, and a signal decoding unit 14. Processes by the respective units will be described later in detail.

The signal comparison unit 103 includes a difference voltage calculation unit 15 and a short-circuit detection unit 16.

With the detected signal transmitted from the signal acquisition unit 101 to the signal comparison unit 103 being set as a second detected signal, the signal comparison unit 103 calculates a difference waveform between the voltage waveform of the second detected signal and the voltage waveform of the decoded signal that corresponds to the first detected signal and that is obtained through decoding by the signal processing unit 102a. The signal comparison unit 103 detects a short-circuit in the field winding on the basis of the calculated difference waveform. Processes by the respective units will be described later in detail.

Arrow B indicates a route of the signal from which short-circuit information has been eliminated. Arrows C indicate routes of the detected signals including short-circuit information.

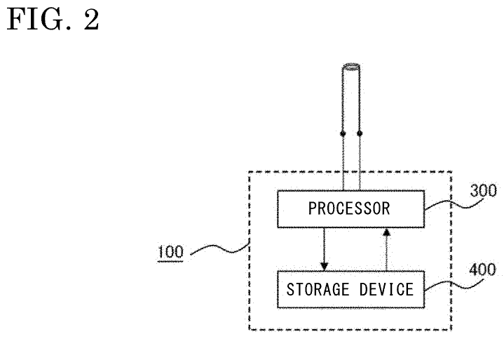

FIG. 2 is an exemplary hardware configuration diagram of the short-circuit detection device 100a according to the present embodiment.

As shown in FIG. 2, the short-circuit detection device 100a includes a processor 300 and a storage device 400 as hardware components.

The storage device 400 is implemented by, for example, a memory storing therein a program that describes a process corresponding to a function of the short-circuit detection device 100a. The processor 300 executes the program stored in the storage device 400, to accomplish the function of the short-circuit detection device 100a. The processor 300 is implemented by a microcomputer, a digital signal processor (DSP), or a processor logically configured in a hardware circuit such as an FPGA. It is noted that a plurality of the processors 300 and a plurality of the storage devices 400 may be in cooperation with each other to accomplish the function of the short-circuit detection device 100a.

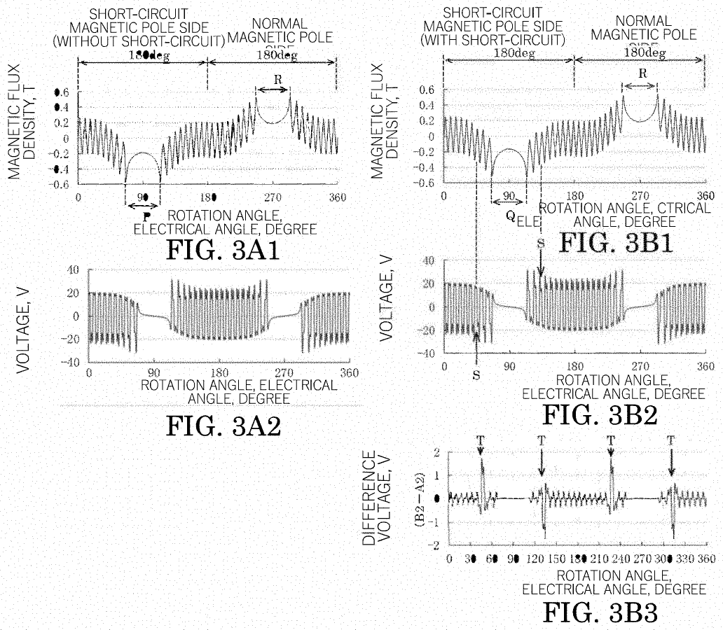

Next, an exemplary voltage waveform detected by the magnetic flux detector 10 will be described with reference to FIG. 3.

FIG. 3(A) illustrates the case of simulating a normal case by the signal processing unit 102a in the present embodiment. FIG. 3(B) illustrates the case of a three-phase short-circuit, in the rotary electric machine 200, that is detected by the signal acquisition unit 101 in the present embodiment.

FIG. 3(A1) shows a magnetic flux density waveform in the case of simulating a normal case by the signal processing unit 102a in the present embodiment. FIG. 3(A2) shows a voltage waveform in the case of simulating the normal case. A process of simulating a normal case will be described later.

FIG. 3(B1) shows a magnetic flux density waveform, in a short-circuited case, that is detected by the signal acquisition unit 101 in the present embodiment. FIG. 3(B2) shows a voltage waveform, from the magnetic flux detector 10, that is detected in the short-circuited case. FIG. 3(B3) shows a difference voltage waveform between the voltage waveform in the short-circuited case and the voltage waveform in the case of simulating the normal case. A process of obtaining the waveform in FIG. 3(B3) will be described later.

It is noted that the voltage waveforms are obtained through electromagnetic field analysis. For the explanation thereof, a diagram showing changes in gap magnetic flux density at rotation angles corresponding to graph B1 is presented in an aligned manner.

In each graph shown in FIG. 3, the horizontal axis indicates the rotation angle of the rotor 1.

Regarding the positional relationship in the rotor 1 of the rotary electric machine 200 shown in FIG. 1, the rotation angle is set to 0 degrees.

A rotation angle of 90 degrees is the central angle of a short-circuit magnetic pole having experienced a short-circuit, and a rotation angle of 270 degrees is the central angle of a normal magnetic pole having experienced no short-circuit. A voltage fluctuation corresponding to leakage magnetic fluxes in 16 rotor slots 5 in each magnetic pole 6 is observed so as to attain symmetry about the center of the said magnetic pole. In a field winding wound over two rotor slots 5 that form a pair, the directions of leakage magnetic fluxes are in a relationship of symmetry about the center of the magnetic pole. Thus, the voltage waveform in FIG. 3(B2) has a rotational symmetry shape about the center of the magnetic pole. In FIG. 3(B2), the positions of short-circuit slots which are a pair of rotor slots 5 over which a field winding having experienced a short-circuit is wound near the center of a short-circuit magnetic pole, are indicated by arrows S.

In FIG. 3(B1), the short-circuit magnetic pole is indicated by arrow Q. In FIG. 3(A1), FIG. 3(B1), and FIG. 3(B2), a normal magnetic pole is indicated by arrow R.

In each short-circuit slot, decrease in the voltage based on decrease, in the field magnetic flux amount, that has occurred owing to the short-circuit is observed as compared to the rotor slots 5 that have experienced no short-circuit and that are located on the short-circuit magnetic pole side near the short-circuit slot and the rotor slots 5 that are located on the normal magnetic pole side at a phase that is different by 180 degrees. Hereinafter, a short-circuit detection method according to the present embodiment will be described using the search coil voltage waveform that includes this short-circuit information.

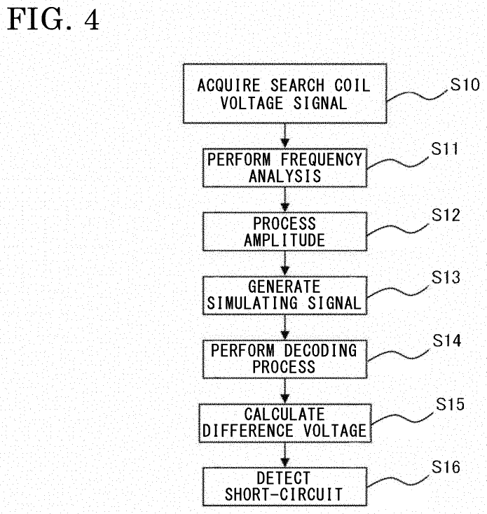

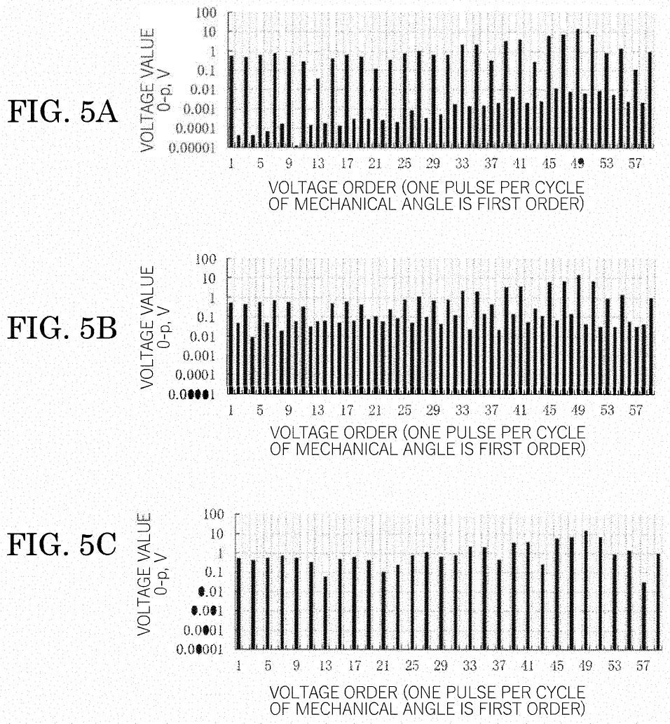

FIG. 4 is a flowchart of the short-circuit detection method according to the present embodiment. FIG. 5 illustrates graphs of frequencies in each of cases, i.e., a normal case, a short-circuited case, and a simulated normal case. In FIG. 5, the horizontal axis indicates a component, of each order, that is included in a voltage waveform, and the vertical axis indicates voltage.

It is noted that an nth-order component (n=1, 2, . . . ) mentioned herein refers to a component that fluctuates n times for one time of rotation of the rotor 1. For example, a first order is the order of a component that fluctuates once for one time of rotation of the rotor 1.

Description will be given with reference to FIG. 5 in accordance with steps of the flowchart in FIG. 4.

In step S10 in FIG. 4, the signal acquisition unit 101 acquires a detected signal from the magnetic flux detector 10. At this time, one detected signal is acquired and set as a first detected signal and a second detected signal. The first detected signal is transmitted to the frequency analysis unit 11 of the signal processing unit 102a. The second detected signal is transmitted to the signal comparison unit 103. The detected signals acquired and transmitted in step S10 include the short-circuit information.

In step S11 in FIG. 4, the frequency analysis unit 11 performs frequency analysis on the waveform of the transmitted first detected signal obtained by the magnetic flux detector 10. FIG. 5(A) shows a graph of frequency in a normal case. FIG. 5(B) shows a graph of a result of the frequency analysis performed by the frequency analysis unit 11. FIG. 5(C) shows a graph of frequency in a simulated normal case.

Further, FIG. 5(B) shows a result of performing the frequency analysis on the voltage waveform in FIG. 3(B2).

It is known from FIG. 5(B) that a component of an order at a rotor slot 5 that has a pitch of 49.5 degrees is regarded as a main component among odd-order components. It is also known that even-order components have significantly increased in FIG. 5(B) as compared to those in FIG. 5(A).

In step S12 in FIG. 4, the filtering processing unit 12a performs a process regarding amplitude on the basis of the result of the frequency analysis. Specifically, a filtering process of setting at least one of absolute values of the even-order components in FIG. 5(B) to be sufficiently smaller than absolute values of the odd-order components, is performed. FIG. 5(C) is a frequency graph in the case of simulating the normal case by performing the filtering process from FIG. 5(B).

Although the filtering process has been described as being performed such that the absolute value of the even-order component is set to be sufficiently smaller than the absolute values of the odd-order components, the filtering process only has to be performed to attain similarity to a state assumed in the normal case. For example, the absolute value of the even-order component may be set to 0. Alternatively, an absolute value of an even-order component smaller than a maximum value among the odd-order components which are components of orders at the rotor slots 5, may be set to be sufficiently smaller than the absolute values of the odd-order components. If the even-order component is set to be smaller, the normal case can be simulated.

In step S13 in FIG. 4, the simulating signal generation unit 13 generates a simulating voltage signal on the basis of the result of the filtering process obtained in step S12.

In step S14 in FIG. 4, the signal decoding unit 14 performs a decoding process by using, for example, inverse Fourier transform on the basis of the simulating voltage signal generated in step S13. On the basis of the absolute values in the result of the frequency analysis in the simulated normal case shown in FIG. 5(C) and the phase in the result of the frequency analysis in the short-circuited case shown in FIG. 5(B), a decoding process is performed so as to obtain a voltage waveform for the simulated normal case shown in FIG. 4(A2). In the series of decoding processes, the phases of the voltage waveforms are not shifted from each other. This is clear also from the fact that the magnetic flux density waveform in FIG. 3(A1) obtained by performing integration on the waveform in FIG. 3(A2) has the same phase as that of the magnetic flux density waveform in FIG. 3(B1).

At the time of the decoding process, the number of times of sampling can be arbitrarily set. Even if a plurality of voltage waveforms are acquired, sampling data having the same rotation angle can be obtained. It is known from FIG. 3(A2) that no decrease in the voltage is observed at a rotation angle that corresponds to the short-circuit slot observed in FIG. 3(B2). That is, it can be said that a state where no short-circuit has occurred is simulated in FIG. 3(A2).

The signal decoding unit 14 transmits the result of the simulation to the difference voltage calculation unit 15 of the signal comparison unit 103.

In step S15 in FIG. 4, the difference voltage calculation unit 15 calculates a difference voltage between the transmitted decoded signal and the second detected signal transmitted from the signal acquisition unit 101. That is, the voltage waveform in FIG. 3(B2) including the short-circuit information is divided by the voltage waveform in FIG. 3(A2) from which the short-circuit information has been eliminated and which simulates the normal case, whereby the difference voltage waveform shown in FIG. 3(B3) is obtained.

The magnitude of the difference voltage is derived from the even-order component processed by the filtering processing unit 12a.

In step S16 in FIG. 4, the short-circuit detection unit 16 detects the short-circuit on the basis of the difference voltage waveform obtained in step S15. Within the rotation angle of 360 degrees, two pairs of short-circuit slots T are detected from FIG. 3(B3), for example. With comparison between a voltage waveform at a detected rotation angle in FIG. 3(B3) and FIG. 3(B2), it is known that one of the two pairs that has experienced decrease in the voltage is a true pair of short-circuit slots.

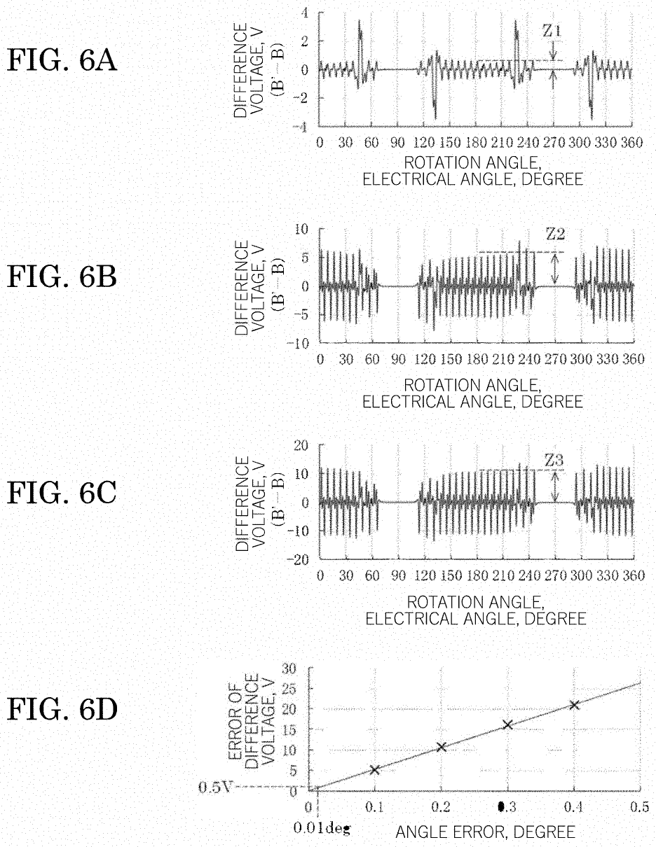

Next, influence of an angle error of the rotation angle will be described regarding short-circuit detection. FIG. 6 shows graphs indicating difference voltage waveforms at respective angle errors, and a graph indicating difference voltage errors at respective angle errors.

In each of FIG. 6(A), FIG. 6(B), and FIG. 6(C), a difference voltage waveform between a voltage waveform on the short-circuit magnetic pole side and a voltage waveform on the normal magnetic pole side at a rotation angle that is different by 180 degrees, is obtained according to an angle error between both voltage waveforms.

FIG. 6(A) shows a graph in which a difference voltage waveform in the case of absence of an angle error has been obtained.

FIG. 6(B) shows a graph in which a difference voltage waveform in the case of an angle error being 0.1 degrees has been obtained.

FIG. 6(C) shows a graph in the case of an angle error being 0.2 degrees.

FIG. 6(D) shows a graph indicating the relationship between angle error and difference voltage error based on FIG. 6(A) to FIG. 6(C).

In FIG. 6(A), a generated difference voltage error Z1 is indicated as 0.5 V. The difference voltage error Z1 is sufficiently smaller than 3.5 V which is a signal level at each short-circuit slot, and thus the probability that erroneous detection occurs is considered to be low.

In FIG. 6(B), a generated difference voltage error Z2 slightly exceeds 5.0 V. Therefore, the probability that erroneous detection occurs in short-circuit detection is considered to be high.

In FIG. 6(C), a difference voltage error Z3 is about 100 V. Therefore, the probability that erroneous detection occurs in short-circuit detection is considered to be even higher.

From FIG. 6(D), it can be said that occurrence of an angle error leads to increase in the difference voltage error in a substantially proportional manner. From FIG. 6(A) to FIG. 6(D), it is considered that the angle error has to be set to be equal to or lower than 0.01 degrees in order to set the difference voltage error to be equal to or lower than 0.5 V.

From FIG. 6, in order to maintain the angle error to be equal to or lower than 0.01 degrees, a time accuracy corresponding to 0.5 μsec., is needed at 50 Hz. Meanwhile, a positional accuracy corresponding to 0.1 mm is needed with a rotor having a diameter of 1.4 m. Therefore, it is difficult to maintain the angle error to be 0.01 degrees, and it is considered to be difficult to decrease a phase shift due to an angle error and an error in a time axis.

Meanwhile, in the present embodiment, the phase of the acquired voltage signal and the phase of the decoded voltage signal are maintained, and thus no angle error occurs.

Therefore, in the present embodiment, a short-circuit can be detected without the need for maintaining the positional accuracy so as to decrease a phase shift.

Although the filtering processing unit 12a in the present embodiment sets the absolute value of an even-order component to be sufficiently smaller than the absolute values of odd-order components, a method that includes setting the absolute values of the odd-order components to be, for example, 1000-fold or otherwise generating a significant difference from the absolute value of the even-order component without changing the absolute value of the even-order component, may be employed.

As described above, in the present embodiment, one detected signal having been acquired is set as a first detected signal and a second detected signal, and a voltage signal generated on the basis of the first detected signal by simulating a normal case and the second detected signal are compared with each other. Thus, without the need for preliminary measurement, a measurement error due to change in an operation condition can be decreased. Since the measurement error is decreased, the number of short-circuits having occurred and the locations of the short-circuits can be accurately detected.

In addition, a short-circuit can be accurately detected without causing any difference voltage error due to errors in a time axis and a rotation angle.

The sampling time for measurement does not need to be shortened in order to decrease the phase shift. Thus, the data amount can be decreased, and the sizes of the storage device and a communication device can be decreased. In association with decrease in data volume, long-term monitoring can be performed.

### Embodiment 2

The short-circuit detection device according to embodiment 1 and a short-circuit detection device according to embodiment 2 are different from each other in terms of a voltage signal to be decoded.

In embodiment 1, a measured voltage value and the voltage value of a voltage signal that simulates a normal case and that has been decoded, are compared with each other to detect a short-circuit. Meanwhile, in embodiment 2, a measured voltage value and the voltage value of a voltage signal having been decoded so as to have a phase that matches the phase of the measured voltage value, are compared with each other to detect a short-circuit.

It is noted that only the difference between embodiment 1 and embodiment 2 will be described below, and descriptions of identical or corresponding features will be omitted. Regarding reference characters as well, portions identical or corresponding to those in embodiment 1 are denoted by the same reference characters, and descriptions thereof will be omitted.

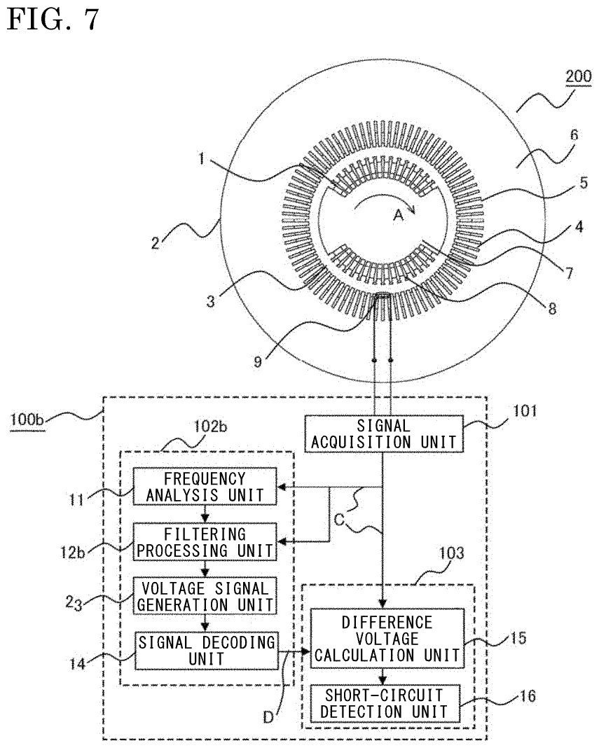

FIG. 7 is a configuration diagram of a short-circuit detection device 100b according to the present embodiment and a rotary electric machine 200 to which the short-circuit detection device 100b is applied. In the present embodiment, a turbine electric generator is used as an example of the rotary electric machine 200.

The short-circuit detection device 100b is connected to the magnetic flux detector 10. The short-circuit detection device 100b includes the signal acquisition unit 101, a signal processing unit 102b, and the signal comparison unit 103.

In the same manner as in embodiment 1, the signal acquisition unit 101 acquires a first detected signal from the magnetic flux detector 10. In the present embodiment, a second detected signal for a magnetic pole different from the magnetic pole for the first detected signal is further acquired.

The signal processing unit 102b generates and outputs a decoded signal corresponding to the first detected signal acquired from the signal acquisition unit 101. The signal processing unit 102b includes the frequency analysis unit 11, a filtering processing unit 12b, a voltage signal generation unit 23, and the signal decoding unit 14. Processes by the respective units will be described later in detail.

Arrow D indicates a route of short-circuit information including information about the location of a short-circuit.

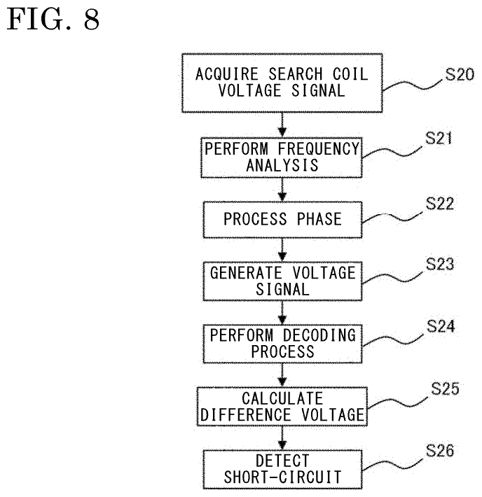

FIG. 8 is a flowchart of a short-circuit detection method according to the present embodiment.

Description will be given in accordance with steps of the flowchart in FIG. 8.

In step S20 in FIG. 8, the signal acquisition unit 101 acquires detected signals from the magnetic flux detector 10 in the same manner as in step S10 in FIG. 4 for embodiment 1. At this time, detected signals for different magnetic poles are acquired and set as the first detected signal and the second detected signal. The first detected signal is transmitted to the frequency analysis unit 11 of the signal processing unit 102b. In addition, the second detected signal is transmitted to the signal comparison unit 103. Further, phase information about the second detected signal is transmitted to the filtering processing unit 12b of the signal processing unit 102b.

In step S21 in FIG. 8, the frequency analysis unit 11 performs frequency analysis on the waveform of the transmitted first detected signal obtained by the magnetic flux detector 10. When frequency analysis is performed, determination is made as to whether or not the first detected signal indicates a short-circuit. Specifically, if the absolute value of an even-order component in the result of the frequency analysis performed on the first detected signal is larger than the absolute values of the odd-order components, determination that a short-circuit has occurred is made. Meanwhile, if the absolute value of the even-order component is sufficiently smaller, determination that a normal case is attained is made. The result of the determination is transmitted as short-circuit information D to the short-circuit detection unit 16.

In step S22 in FIG. 8, the filtering processing unit 12b performs a process regarding phase on the basis of the result of the frequency analysis. Specifically, a process of shifting a phase of each order of the first detected signal such that the phase matches a phase of the second detected signal, is performed. In the filtering processing unit 12b in the present embodiment, although the phase is shifted, the absolute value at each order is not changed.

In step S23 in FIG. 8, the voltage signal generation unit 23 generates a voltage signal on the basis of the result of the filtering process obtained in step S22.

In step S24 in FIG. 8, the signal decoding unit 14 performs a decoding process by using, for example, inverse Fourier transform on the basis of the voltage signal generated in step S23. At the time of decoding, the decoding process is performed so as to be adjusted to the number of times of sampling the second detected signal. The signal decoding unit 14 transmits the result of the decoding to the difference voltage calculation unit 15 of the signal comparison unit 103.

In step S25 in FIG. 8, the difference voltage calculation unit 15 calculates a difference voltage between the decoded first detected signal and the second detected signal transmitted from the signal acquisition unit 101. That is, a difference voltage between the first voltage signal and the second voltage signal having phases that match each other, can be obtained.

In step S26 in FIG. 8, the short-circuit detection unit 16 detects a short-circuit on the basis of the difference voltage waveform obtained in step S25 and the short-circuit information D. If the first detected signal does not indicate occurrence of any short-circuit, a short-circuit can be detected by comparison with a state in the normal case in the same manner as in embodiment 1. Meanwhile, if the first detected signal indicates occurrence of a short-circuit, the short-circuit can be detected by comparison in consideration of the location of the occurrence of the short-circuit.

In the present embodiment, a second detected signal for a magnetic pole different from that for a first detected signal is acquired in step S20. However, for example, a detected signal that does not indicate occurrence of any short-circuit may be acquired as the first detected signal. A detected signal that does not indicate occurrence of any short-circuit may be, for example, held in advance in a signal storage device connected to the signal acquisition unit 101, and the signal acquisition unit 101 may acquire the detected signal from the signal storage device.

In the short-circuit detection device 100b according to the present embodiment, preliminary measurement is unnecessary and an adverse influence of load fluctuation can be avoided in the same manner as in embodiment 1 since decoding is performed such that, even if two voltages are detected at different timings by the magnetic flux detector 10, the phases of both voltages match each other.

Further, phases can be adjusted with the order of each rotor slot and the order of a main magnetic flux of a magnetic flux density obtained by integrating a detected signal. Thus, comparison can be performed in a state where the difference voltage error is decreased. A short-circuit in a field winding can be accurately detected.

In addition, it is unnecessary to acquire signal data having a large volume such that temporal accuracy and spatial accuracy are fine.

Although embodiments 1 and 2 have been described as implementation examples of the present disclosure, the configuration of the present disclosure is not limited to the configurations in embodiments 1 and 2, and the configurations of embodiments 1 and 2 may be combined as necessary or each configuration may be partially modified or partially omitted, without departing from the gist of the present disclosure.

### DESCRIPTION OF THE REFERENCE CHARACTERS

100a, 100b short-circuit detection device

200 rotary electric machine

1 rotor

2 stator

3 gap

4 rotor core

5 rotor slot

6 magnetic pole

7 stator core

8 stator slot

9 multiphase winding

10 magnetic flux detector

11 frequency analysis unit

12a, 12b filtering processing unit

13 simulating signal generation unit

14 signal decoding unit

15 difference voltage calculation unit

16 short-circuit detection unit

23 voltage signal generation unit

101 signal acquisition unit

102a, 102b signal processing unit

103 signal comparison unit

1. A short-circuit detection device comprising:
a signal acquirer to acquire, from a magnetic flux detector configured to detect a magnetic flux generated in a gap between a rotor and a stator of a rotary electric machine, one detected signal based on the magnetic flux and set the one detected signal as a first detected signal and a second detected signal;
a signal processor to perform frequency analysis on the first detected signal, and generate and decode a voltage signal simulating a voltage state assumed in a normal case; and
a signal comparator to perform comparison between a decoded signal obtained through the decoding by the signal processor and the second detected signal transmitted from the signal acquirer, to detect a short-circuit in a field winding of the rotary electric machine.

2. The short-circuit detection device according to claim 1, wherein
the signal processor performs setting such that at least one of absolute values of even-order components in a result of the frequency analysis performed on the first detected signal, is smaller than absolute values of odd-order components.

3. The short-circuit detection device according to claim 2, wherein
an absolute value of an even-order component that is included among the even-order components and that is smaller than a maximum value among the odd-order components which are components of orders at slots of the rotor, is set to be smaller than the odd-order components.

4. The short-circuit detection device according to claim 2, wherein
the absolute value of the even-order component is set to 0.

5. A short-circuit detection device comprising:
a signal acquirer to acquire, from a magnetic flux detector configured to detect a magnetic flux generated in a gap between a rotor and a stator of a rotary electric machine, detected signals for different magnetic poles, the detected signals being based on the magnetic flux, the detected signals being acquired as a first detected signal and a second detected signal;
a signal processor to perform frequency analysis on the first detected signal, and generate and decode a voltage signal having a phase that matches a phase of the second detected signal; and
a signal comparator to perform comparison between a decoded signal obtained through the decoding by the signal processor and the second detected signal, to detect a short-circuit in a field winding of the rotary electric machine.

6. The short-circuit detection device according to claim 5, wherein
the signal acquirer sets, as the first detected signal, a voltage signal prestored in a signal storage device.

7. A short-circuit detection method comprising:
a step of acquiring, from a magnetic flux detector configured to detect a magnetic flux generated in a gap between a rotor and a stator of a rotary electric machine, one detected signal based on the magnetic flux, and setting the one detected signal as a first detected signal and a second detected signal;
a step of performing frequency analysis on the first detected signal, and generating and decoding a voltage signal simulating a voltage state assumed in a normal case; and
a step of performing comparison between a decoded signal obtained through the decoding and the second detected signal, to detect a short-circuit in a field winding of the rotary electric machine.

8. A short-circuit detection method comprising:
a step of acquiring, from a magnetic flux detector configured to detect a magnetic flux generated in a gap between a rotor and a stator of a rotary electric machine, detected signals for different magnetic poles, the detected signals being based on the magnetic flux, the detected signals being acquired as a first detected signal and a second detected signal;
a step of performing frequency analysis on the first detected signal, and generating and decoding a voltage signal having a phase that matches a phase of the second detected signal; and
a step of performing comparison between a decoded signal obtained through the decoding and the second detected signal, to detect a short-circuit in a field winding of the rotary electric machine.
